(19) United States
(12) Patent Application Publication
(10) Pub. No.: US 2011/0147192 A1
(43) Pub. Date: Jun. 23, 2011

(54) PROJECTED CAPACITIVE TOUCH PANEL

(75) Inventor: Jane HSU, Guishan Township (TW)

(73) Assignee: DerLead Investment Ltd., Taipei (TW)

(21) Appl. No.: 12/965,957

(22) Filed: Dec. 13, 2010

(30) Foreign Application Priority Data
Dec. 18, 2009 (TW) 098223713

(51) Int. Cl. H03K 17/975

(52) U.S. Cl. 200/600

(57) ABSTRACT

A projected capacitive touch panel has an upper substrate and a lower substrate. The upper substrate has multiple upper conducting layers, and each upper conducting layer has multiple upper sensor units serially connected. The upper substrate further has an insulating ink layer being non-transparent, formed on a perimeter of the bottom of the upper substrate, covering an edge of the upper sensor unit located on one end of each upper conducting layer in a direction, overlapping with the lower ports and the lower wires of the lower substrate, and having multiple reserved slots, each formed through a portion of the insulating ink layer overlapping with a corresponding upper sensor unit, and multiple conductors, each mounted in a corresponding reserved slot. The insulating ink layer masks the wires and ports on the lower and upper substrates, thereby eliminating the use of a masking cover, saving the cost and thinning the product.

### BACKGROUND OF THE INVENTION

1. Field of the Invention

The present invention relates to a touch panel, and more particularly to a projected capacitive touch panel eliminating the use of a masking cover for masking wires and ports on the substrates.

2. Description of the Related Art

Based on technical concept, touch panels can be classified into capacitive touch panels, resistive touch panels, surface acoustic touch panels, infrared touch panels and the like. Among them, the capacitive touch panels are advantageous in being waterproof and abrasion-resistant and having higher light transmittance, and are mainly applied to high-grade displays. Specifically, the capacitive touch panels can be further divided into surface capacitive touch panels and projected capacitive touch panels. As the projected capacitive touch panels serve for multi-touch operation, they are extensively applied to audio and video products nowadays.

The projected capacitive touch panels are usually composed of two substrates. Each substrate has a plurality of sensor units mounted and serially connected thereon and formed by indium tin oxide (ITO), and a plurality of wires formed alongside a perimeter of the substrate. The wires are non-transparent, and both ends of each wire are respectively connected with one of the sensor units and a flexible printed circuit board (PCB) mounted on a side of the substrate to transmit signals of the sensor units to the flexible PCB. To take aesthetic aspect into account, a masking cover is mounted on a top of the touch panel to cover the wires, on which non-transparent ink are painted. However, the added masking cover not only increases the production cost but also thickens the touch panels, making the miniaturization requirement hard to be fulfilled.

### SUMMARY OF THE INVENTION

An objective of the present invention is to provide a projected capacitive touch panel eliminating the use of a masking cover for masking wires and ports on the substrates.

To achieve the foregoing objective, the projected capacitive touch panel has an insulating layer, a flexible printed circuit board, a lower substrate and an upper substrate.

The insulating layer has a recess formed in one edge thereof. The flexible printed circuit board is mounted in the recess of the insulating layer.

The lower substrate is mounted on bottoms of the insulating layer and the flexible printed circuit board, and has an electromagnetic shielding layer, multiple lower conducting layers, multiple lower ports and multiple lower wires. The electromagnetic shielding layer is formed on a bottom of the lower substrate. The lower conducting layers are parallelly formed on a top of the lower substrate, and align in a first direction. Each lower conducting layer has multiple lower sensor units serially connected. Each lower port is formed on one side of one of the lower conducting layers. The lower wires are formed on the top of the lower substrate, and are equal to the lower ports in number. One end of each lower wire is connected to one of the lower ports, and the other end of the lower wire is connected to the flexible printed circuit board.

The upper substrate is mounted on tops of the insulating layer and the flexible, and has multiple upper conducting layers, an insulating ink layer, multiple upper ports and multiple upper wires.

The upper conducting layers are parallelly formed on a bottom of the upper substrate, and align in a second direction perpendicular to the first direction. Each upper conducting layer has multiple upper sensor units serially connected.

The insulating ink layer is non-transparent, is formed on a perimeter of the bottom of the upper substrate, covers an edge of the upper sensor unit located on one end of each upper conducting layer in the second direction, overlaps with the lower ports and the lower wires of the lower substrate, and has multiple reserved slots and multiple conductors. Each reserved slot is formed through a portion of the insulating ink layer overlapping with a corresponding upper sensor unit. Each conductor is mounted in a corresponding reserved slot. Each upper port is formed on a bottom of a corresponding conductor.

The upper wires are formed on a bottom of the insulating ink layer, and are equal to the upper ports in number. One end of each upper wire is connected to a corresponding upper port, and the other end of the upper wire is connected to the flexible printed circuit board.

Given the structure that the non-transparent insulating ink layer is formed on the bottom of the upper substrate, the upper wires are respectively formed between the corresponding upper sensor units and the flexible printed circuit board and formed on the bottom of the insulating ink layer, and the insulating ink layer overlaps with the lower ports and the lower wires of the lower conducting layer, the insulating ink layer can mask the upper wires and the upper ports of the upper substrate and the lower wires and the lower ports of the lower substrate when viewed from the top of the top substrate. Accordingly, a masking cover serving to cover the wires and ports on the substrates can be eliminated to save the cost and thickness of the product to which the touch panel of the present invention is applied.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a projected capacitive touch panel in accordance with the present invention;

FIG. 2 is a partially exploded view of the projected capacitive touch panel in FIG. 1 when an upper substrate of the projected capacitive touch panel is lifted;

FIG. 3 is a perspective view of a lower substrate of the projected capacitive touch panel in FIG. 1;

FIG. 4 is an enlarged bottom view of an upper substrate of the projected capacitive touch panel in FIG. 1;

FIG. 5 is a cross-sectional view of the upper substrate taken along a line 5-5 in FIG. 4; and

FIG. 6 is a top view of the projected capacitive touch panel in FIG. 1.

### DETAILED DESCRIPTION OF THE INVENTION

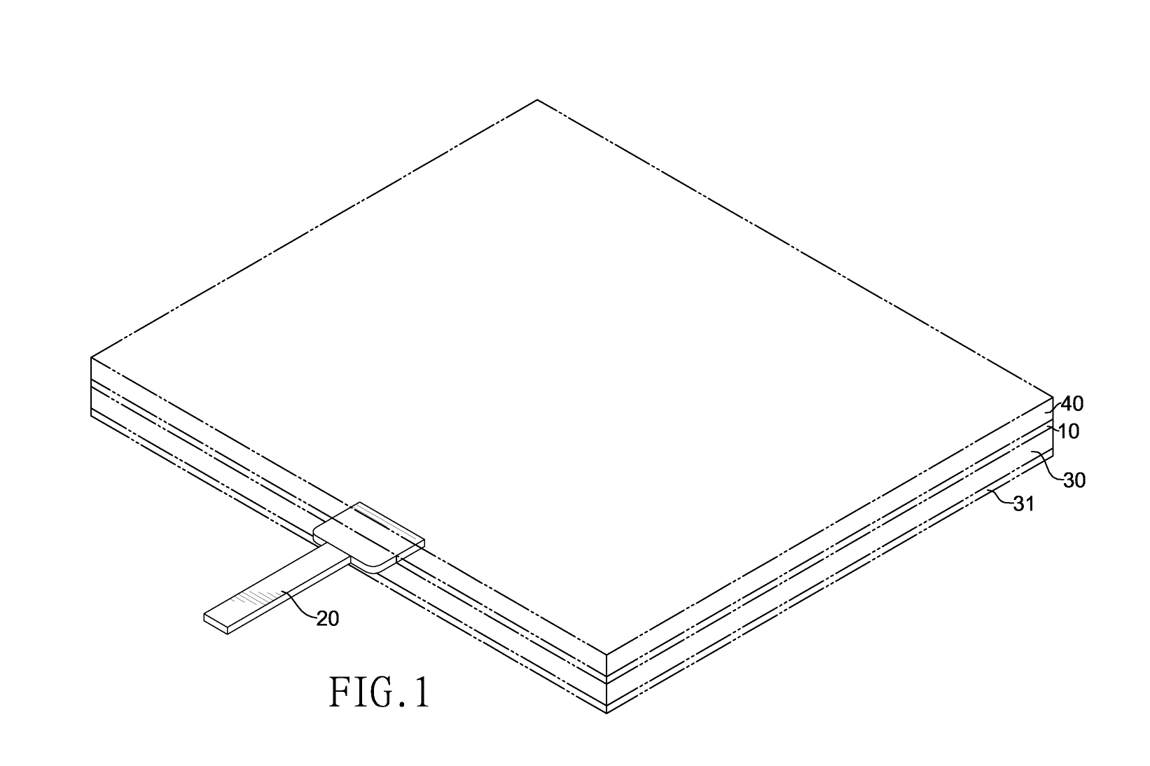

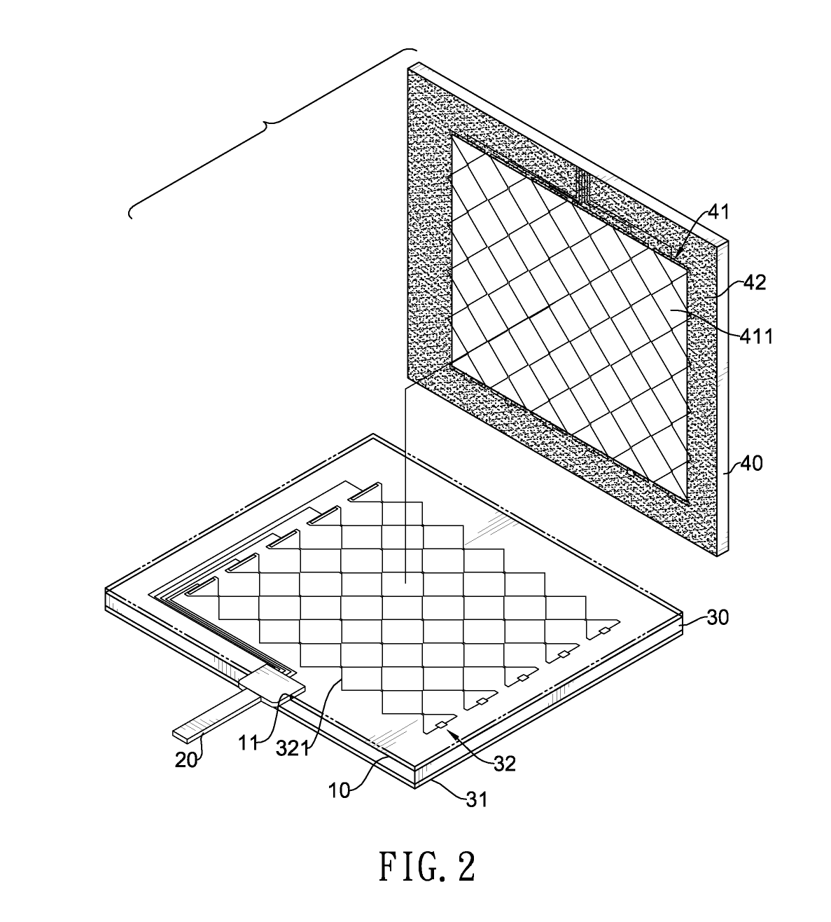

With reference to FIGS. 1 and 2, a projected capacitive touch panel in accordance with the present invention has an insulating layer 10, a flexible printed circuit board (PCB) 20, a lower substrate 30 and an upper substrate 40.

The insulating layer 10 has a recess 11 formed in one edge thereof.

The flexible PCB 20 is mounted in the recess 11 of the insulating layer 10.

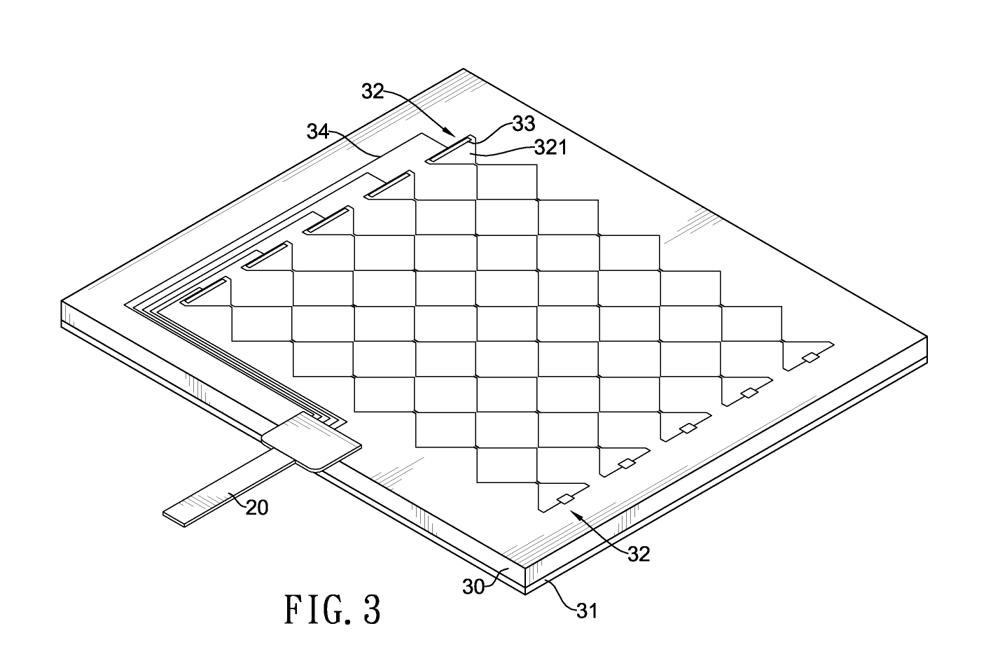

With reference to FIG. 3, technically, the structure of the lower substrate 30 is identical to those of conventional projected capacitive touch panels. The lower substrate 30 is mounted on bottoms of the insulating layer 10 and the flexible PCB 20, and has an electromagnetic shielding layer 31, multiple lower conducting layers 32, multiple lower ports 33 and multiple lower wires 34. The electromagnetic shielding layer 31 is formed on a bottom of the lower substrate 30 and is composed of ITO. The lower conducting layers 32 are parallelly formed on a top of the lower substrate 30, and align in a first direction. Each lower conducting layer 32 has multiple lower sensor units 321 serially connected and composed of ITO. Each lower port 33 is formed on one side of one of the lower conducting layers 32, is perpendicular to the first direction, and is formed by a conducting material. The lower wires 34 are formed on the top of the lower substrate 30, are equal to the lower ports 33 in number, and may be silver wires. One end of each lower wire 34 is connected to one of the lower ports 33, and the other end of the lower wire 34 is connected to the flexible PCB 20.

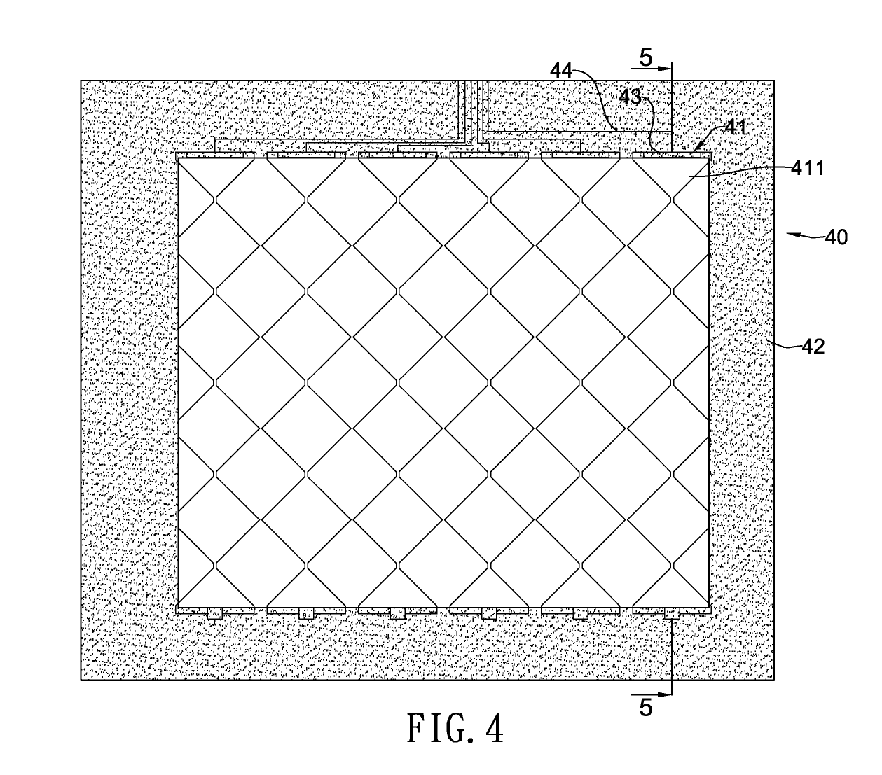

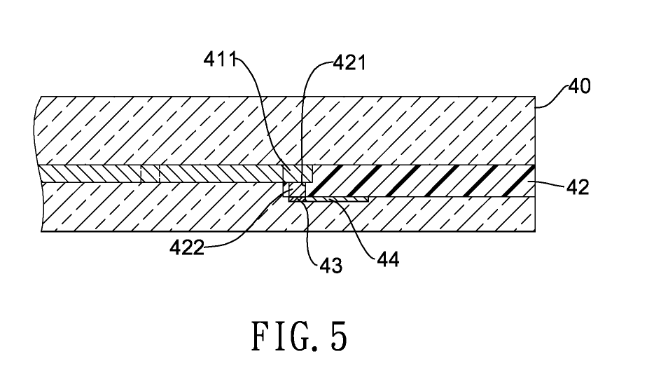

With reference to FIG. 4, the upper substrate 40 is mounted on tops of the insulating layer 10 and the flexible PCB 20, has multiple upper conducting layers 41, an insulating ink layer 42, multiple upper ports 43 and multiple upper wires 44. The upper conducting layers 41 are parallelly formed on a bottom of the upper substrate 40, align in a second direction perpendicular to the first direction, and correspond to a portion of the top of the lower substrate 30 unoccupied by the lower sensor units 321. Each upper conducting layer 41 has multiple upper sensor units 411 serially connected and composed of ITO. The insulating ink layer 42 is non-transparent, is formed on a perimeter of the bottom of the upper substrate 40, covers an edge of the upper sensor unit 411 located on one end of each upper conducting layer 41 in the second direction, and overlaps with the lower ports 33 and the lower wires 34 of the lower substrate 30. With reference to FIG. 5, the insulating ink layer 42 has multiple reserved slots 421 and multiple conductors 422. Each reserved slot 421 is formed through a portion of the insulating ink layer 42 overlapping with a corresponding upper sensor unit 41. Each conductor 422 is mounted in a corresponding reserved slot 421, and a corresponding upper port 43 is formed on a bottom of the conductor 422. The upper wires 44 are formed on a bottom of the insulating ink layer 42, are equal to the upper ports 43 in number, are respectively connected with the upper ports 43, and may be silver wires. One end of each upper wire 44 is connected to a corresponding upper port 43, and the other end of the upper wire 44 is connected to the flexible PCB 20.

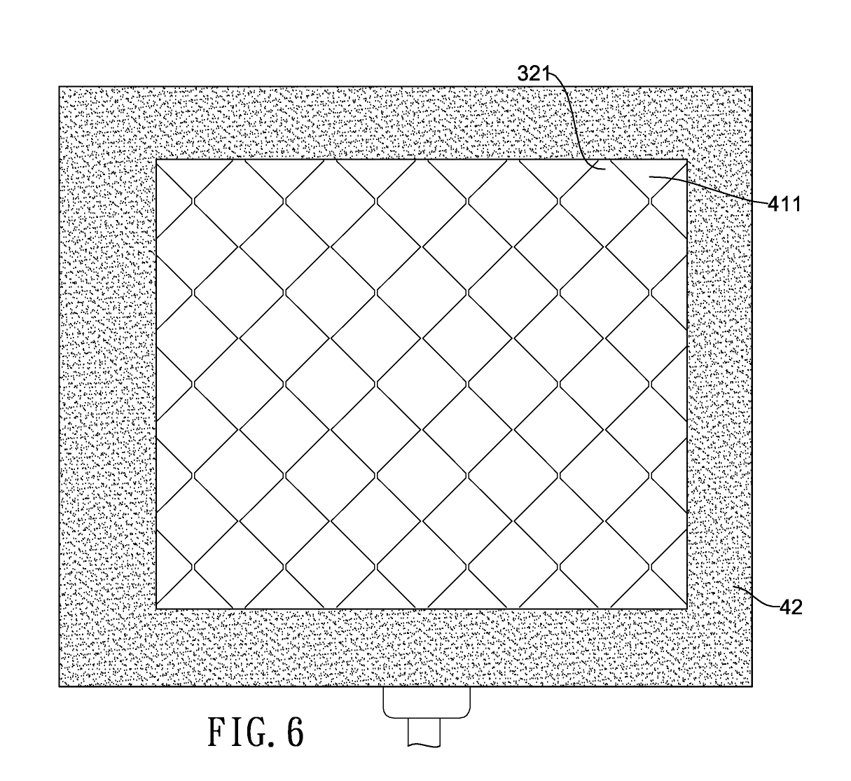

Given the insulating ink layer 42 formed around a perimeter of the bottom of the upper substrate 40, the upper wires 44 is formed on the bottom of the insulating ink layer 42, and one end of each upper wire 44 is connected to the flexible PCB 20 and the other end of the upper wire 44 is connected to a corresponding upper port 43. Accordingly, signals of each upper sensor unit 411 of the upper conducting layer 41 can be transmitted to the flexible PCB 20 through a corresponding upper port 43 and a corresponding conductor 422 electrically connected between the upper sensor unit 411 and a corresponding upper wire. Since the insulating ink layer 42 is non-transparent and overlaps with the lower ports 33 and the lower wires 34 of the lower substrate 30, with reference to FIG. 6, when viewed from the top of the touch panel, the insulating ink layer 42 can mask the upper wires 44 of the upper substrate 40, the upper ports 43, the lower wires 34 of the lower substrate 30, and the lower ports 33. When the touch panel of the present invention is applied to an electronic product, a masking cover is not additionally required to cover the upper wires 44, the upper ports 43, the lower wires 34 and the lower ports 33, thereby saving the cost of the product and thinning the product.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A projected capacitive touch panel, comprising:
an insulating layer having a recess formed in one edge thereof;
a flexible printed circuit board mounted in the recess of the insulating layer;
a lower substrate mounted on bottoms of the insulating layer and the flexible printed circuit board, and having:
an electromagnetic shielding layer formed on a bottom of the lower substrate;
multiple lower conducting layers parallelly formed on a top of the lower substrate, and aligning in a first direction, each lower conducting layer having multiple lower sensor units serially connected;
multiple lower ports, each lower port formed on one side of one of the lower conducting layers; and
multiple lower wires formed on the top of the lower substrate, and being equal to the lower ports in number, wherein one end of each lower wire is connected to one of the lower ports, and the other end of the lower wire is connected to the flexible printed circuit board; and
an upper substrate mounted on tops of the insulating layer and the flexible, and having:
multiple upper conducting layers parallelly formed on a bottom of the upper substrate, and aligning in a second direction perpendicular to the first direction, each upper conducting layer having multiple upper sensor units serially connected;
an insulating ink layer being non-transparent, formed on a perimeter of the bottom of the upper substrate, covering an edge of the upper sensor unit located on one end of each upper conducting layer in the second direction, overlapping with the lower ports and the lower wires of the lower substrate, and having:
multiple reserved slots, each reserved slot formed through a portion of the insulating ink layer overlapping with a corresponding upper sensor unit; and
multiple conductors, each conductor mounted in a corresponding reserved slot;
multiple upper ports, each upper port formed on a bottom of a corresponding conductor; and
multiple upper wires formed on a bottom of the insulating ink layer, and being equal to the upper ports in number, wherein one end of each upper wire is connected to a corresponding upper port, and the other end of the upper wire is connected to the flexible printed circuit board.

2. The projected capacitive touch panel as claimed in claim 1, wherein the upper wires and the lower wires are silver wires.

3. The projected capacitive touch panel as claimed in claim 1, wherein the electromagnetic shielding layer is formed by indium tin oxide.

4. The projected capacitive touch panel as claimed in claim 2, wherein the electromagnetic shielding layer is formed by indium tin oxide.

5. The projected capacitive touch panel as claimed in claim 1, wherein the upper sensor units of the upper conducting layer and the lower sensor units of the lower conducting layer are formed by indium tin oxide.

6. The projected capacitive touch panel as claimed in claim 2, wherein the upper sensor units of the upper conducting layer and the lower sensor units of the lower conducting layer are formed by indium tin oxide.

7. The projected capacitive touch panel as claimed in claim 3, wherein the upper sensor units of the upper conducting layer and the lower sensor units of the lower conducting layer are formed by indium tin oxide.

8. The projected capacitive touch panel as claimed in claim 4, wherein the upper sensor units of the upper conducting layer and the lower sensor units of the lower conducting layer are formed by indium tin oxide.
